(19) United States
(12) Patent Application Publication
(10) Pub. No.: US 2024/0274496 A1
(43) Pub. Date: Aug. 15, 2024

(54) CHIP MODULE, CIRCUIT BOARD AND ELECTRONIC DEVICE

(71) Applicant: BITMAIN TECHNOLOGIES INC., Beijing (CN)

(72) Inventors: Yongbo GE, Beijing (CN); Mingliang HAO, Beijing (CN); Zhongxin LI, Beijing (CN); Yang LIU, Beijing (CN); Haitang HU, Beijing (CN); Zhihao ZHU, Beijing (CN); Te PI, Beijing (CN)

(21) Appl. No.: 18/648,207

(22) Filed: Apr. 26, 2024

Related U.S. Application Data
(63) Continuation of application No. PCT/CN2022/118838, filed on Sep. 14, 2022.

(30) Foreign Application Priority Data
Oct. 26, 2021 (CN) 202111246470.2

(51) Int. Cl. H01L 23/373; H01L 23/00; H01L 25/065

(52) U.S. Cl. CPC H01L 23/373; H01L 24/32; H01L 25/0655; H01L 2224/32245; H01L 2924/1433

(57) ABSTRACT

The present disclosure relates to a chip module, a circuit board and an electronic device. The chip module includes: a chip; a heat-dissipating metal sheet, and a thermal conductive layer located between the chip and the heat-dissipating metal sheet, where a thermal conductive material included in the thermal conductive layer is a phase change material or a thermal conductive paste.

### CROSS-REFERENCE TO RELATED APPLICATIONS

The present application is a continuation of International Application No. PCT/CN2022/118838, filed on Sep. 14, 2022, which claims priority to Chinese Application No. 202111246470.2, filed on Oct. 26, 2021. These applications are hereby incorporated by reference in their entireties.

### TECHNICAL FIELD

The present disclosure relates to the technical field of chips, but is not limited to the technical field of chips, and in particular relates to a chip module, a circuit board and an electronic device.

### BACKGROUND

With the process improvement, the heat source of a chip (Die) is becoming smaller and smaller, yet the problem of thermal expansion becomes more and more prominent. The temperature difference between the chip and a heat sink in the traditional gel scheme can be 20° C. In the prior art, adopting a new process of chip packaging BSM (Back Side Metal) and a metal welding can significantly reduce the temperature difference between the chip and the heat sink, but it is limited by a capacity of a packaging and testing factory and a resulting welding problem, thus, the operability in actual production is low.

### SUMMARY

The present disclosure provides a chip module, a circuit board and an electronic device.

According to a first aspect of an embodiment of the present disclosure, a chip module is provided, including:
a chip;
a heat-dissipating metal sheet;
a thermal conductive layer located between the chip and the heat-dissipating metal sheet, where a thermal conductive material included in the thermal conductive layer is a phase change material or a thermal conductive paste.

According to a second aspect of an embodiment of the present disclosure, a circuit board is provided, including:
a PCB (Printed Circuit Board);
a plurality of chip modules as provided in the first aspect of the above embodiment;
where one side of each of the chip modules away from the heat-dissipating metal sheet is fixed on the PCB.

In a third aspect of an embodiment of the present disclosure, an electronic device is provided, which includes a circuit board provided by any technical scheme of the aforementioned second aspect.

Illustratively, the technical scheme provided by the embodiment of the present disclosure may include the following beneficial effects:
the present disclosure mainly includes a chip, a heat-dissipating metal sheet and a thermal conductive layer, where the thermal conductive layer is located between the chip and the heat-dissipating metal sheet and cooperates with the heat-dissipating metal sheet to dissipate heat from the chip. The thermal conductive material included in the thermal conductive layer is: a phase change material or a thermal conductive paste, that is, the present disclosure utilizes the characteristics of good interfacial wettability and high thermal conductivity of the phase change material or the thermal conductive paste, which cooperates with the heat-dissipating metal sheet on the top to realize heat dissipation.

It is to be understood that both the foregoing general description and the following detailed description are exemplary and explanatory only and are not restrictive of the present disclosure.

### BRIEF DESCRIPTION OF DRAWINGS

The accompanying drawings here, which are incorporated in and constitute a part of this description, illustrate embodiments consistent with the present disclosure and together with the description, serve to explain the principles of the present disclosure.

FIG. 1 is a schematic structural diagram of a chip module according to an exemplary embodiment.

FIG. 2 is a schematic structural diagram of another chip module according to an exemplary embodiment.

### DESCRIPTION OF REFERENCE NUMERALS

100—chip;
200—heat-dissipating metal sheet;
300—thermal conductive layer;
400—PCB;
500—heat sink;
600—thermal conductive gel

### DESCRIPTION OF EMBODIMENTS

Reference will now be made in detail to exemplary embodiments, examples of which are illustrated in the accompanying drawings. When the following description refers to the accompanying drawings, unless otherwise indicated, the same numbers in different drawings indicate the same or similar elements. The implementations described in the following exemplary embodiments do not represent all embodiments consistent with the present disclosure. Rather, they are merely examples of devices and methods consistent with some aspects of the present disclosure as detailed in the appended claims.

In addition, the terms indicating the direction and orientation in this specification, such as “up”, “down”, “long”, “wide” and “high”, are intended to explain the relative positional relationship of each constituent component, and are not intended to limit the orientation and installation position of each constituent component.

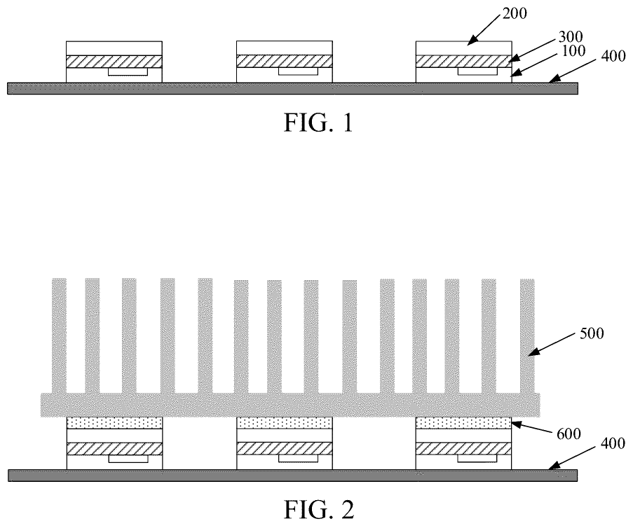

FIG. 1 is a schematic structural diagram of a chip module according to an exemplary embodiment. The chip module can be applied to various types of electronic device. The chip module can include various chips. The chip may include various computing chips and/or image processing chips. The computing chip can be used for mining calculation of a blockchain, etc.

As shown in FIG. 1, the chip module mainly includes a chip 100, a heat-dissipating metal sheet 200 and a thermal conductive layer 300. The thermal conductive layer 300 is located between the chip 100 and the heat-dissipating metal sheet 200.

The chip can be various types of chips, such as but not limited to a computing chip and/or an image processing chip (GPU). The computing chip includes but is not limited to an application specific integrated circuit (ASIC) chip.

The heat-dissipating metal sheet 200 can be made of various metals with good heat-dissipating performance that are solid at normal temperature (or room temperature). Illustratively, the heat-dissipating metal sheet 200 may be a copper sheet, an aluminum sheet, an alloy metal sheet or the like.

The size of the chip heat source is getting smaller and smaller with the process improvement, thus the problem of chip thermal expansion is becoming more and more prominent. The thermal expansion refers to a phenomenon that the physical properties such as size, shape and volume of a material change reversibly when the temperature changes. In the related art, the temperature difference between the chip and the heat sink reaches 20° C., and the heat dissipation effect is poor. Therefore, the present disclosure provides a chip module, which utilizes the characteristics of good interfacial wettability and high thermal conductivity of the phase change material or the thermal conductive paste, which cooperates with the heat-dissipating metal sheet on the top to realize the heat dissipation.

Illustratively, in this embodiment, the phase change material or the thermal conductive paste is used as the thermal conductive layer 300, which is disposed between the chip 100 and the heat-dissipating metal sheet 200, and the characteristics of good interfacial wettability, high thermal conductivity and thin coating thickness of the phase change thermal conductive material or thermal conductive paste are fully utilized, and better heat dissipation is achieved by cooperating with the heat-dissipating metal sheet.

Here, the phase change material is a kind of heat-enhanced polymer, which refers to a substance that can absorb a large amount of latent heat during a phase change process when a state of the substance is changed under a condition of constant temperature, which also reduces a thermal resistance between the chip 100 and the heat-dissipating metal sheet 200, and can also fill a gap between the interfaces, effectively removing the air between the interfaces with high reliability. The phase change material in this embodiment can be an organic phase change material or an inorganic phase change material. In this embodiment, the phase change material is not specifically limited as long as it meets requirements of thermal conductivity and the like.

The thermal conductive paste is a material with high thermal conductivity, which may include at least one or more of thermal conductive gel, thermal conductive silicone grease, thermal conductive silica gel and thermal conductive mud, and this embodiment is not limited by way of example.

Illustratively, the thermal conductivity of the thermal conductive layer 300 of this embodiment is at least not less than 4 W/(m·K).

In order to ensure the heat dissipation for the chip 100 in this embodiment, this embodiment requires that the thermal conductivity of the thermal conductive layer 300 should not be less than 4 W/(m·K), for example, the thermal conductivity of the thermal conductive layer 300 is 5 W/(m·K) or 10 W/(m·K), etc., so as to facilitate to cooperate with the heat-dissipating metal sheet 200 to realize the thermal expansion of the chip 100 and achieve a better heat dissipation effect.

Illustratively, the thickness of the thermal conductive layer 300 in this embodiment may be 0.05 mm to 0.1 mm, for example, the thickness of the thermal conductive layer 300 is 0.05 mm, 0.06 mm or 0.1 mm, etc. This can not only ensure that the thermal conductivity of the thermal conductive layer 300 meets the requirements, but also reduce the overall thickness of the chip module due to the thin coating.

In addition, as the phase change material or the thermal conductive paste has the characteristics of high thermal conductivity, thin coating and good interfacial wettability, the contact thermal resistance between the chip and the heat sink can be reduced, and the phase change material or the thermal conductive paste does not require high-temperature furnace curing or time waiting.

In one embodiment, the chip module further includes a connection layer (not shown in the figures). The connection layer is used to fix the heat-dissipating metal sheet 200 and the chip 100.

In this embodiment, the connection layer can be located in an edge area of the chip, and the thermal conductive layer 300 is located at least in a middle area of the chip 100. Here, the edge area is located outside the middle area.

Illustratively, the connection layer is disposed in the edge area of the chip 100 in a [symbol] word shape, and the thermal conductive layer 300 is coated inside the [symbol] -word shaped area. At this time, the connection layer and the thermal conductive layer 300 are both located between the heat-dissipating metal sheet and the chip, and the connection layer fixes the heat-dissipating metal sheet 200 and the chip 100 to prevent the relative positions of the heat-dissipating metal sheet 200 and the chip 100 from changing.

Illustratively, the connection layer of this embodiment may be an adhesive layer including a glue. The adhesive layer adheres the heat-dissipating metal sheet 200 and the chip 100 to prevent the relative positions of the heat-dissipating metal sheet 200 and the chip 100 from changing.

Here, the chip 100 is a bare chip (Die), or it could be referred as a wafer, which is a small piece of semiconductor material, on which a given functional circuit can be fabricated, yet the die has not been added with a heat-dissipating structure and packaged, therefore, it cannot be directly used. In this embodiment, as the chip 100 is not subjected to the BSM process and does not need to be soldered, the die can be directly adhered and connected with the heat-dissipating metal sheet 200 by using the glue, and the relative position of the heat-dissipating metal sheet 200 and the chip 100 is fixed.

The size of the bare chip or the size of chip heat source is getting smaller and smaller with the process improvement, thus, the problem of chip thermal expansion is becoming more and more prominent. In the prior art, a method of a combination of the chip BSM packaging and a metal welding can significantly reduce the temperature difference between the chip and the heat sink, but it is limited by the capacity of the packaging and testing factory and the existing welding problems, and the operability in actual production is low.

However, in this embodiment, the thermal conductive layer 300 is disposed between the bare chip and the heat-dissipating metal sheet 200, and the heat expansion is achieved by using the high thermal conductive material of the thermal conductive layer 300, and it does not require the BSM process or the welding for the bare chip, therefore, it has high operability in actual production.

Here, the BSM refers to the back side metal process, that is, a process of depositing metal on the back side of the wafer, which is convenient to weld the heat-dissipating metal sheet on the chip and realize the thermal expansion of the chip 100. However, this process requires extremely high packaging capacity for the packaging and testing factory and high welding technology, which not only increases the heat source area of the chip, but also is not conducive to actual production.

In the above embodiment, the characteristics of thin coating and good wettability of the high thermal conductivity materials are fully exploited, and the metal welding layer is replaced by the thermal conductive layer 300. Although it is somewhat similar to the traditional structure, the process is completely different, and there is no need for a BSM process or a welding for the bare chip, which greatly reduces the production difficulty and improves the operability in actual production.

In this embodiment, the material of the glue is not limited, and it can be double-sided adhesive, hot melt adhesive or epoxy resin bonded glue, as long as it can connect and fix the heat-dissipating metal sheet 200 and the chip 100, so as to ensure that the relative position of the heat-dissipating metal sheet 200 and the chip 100 does not change to improve the reliability of the chip module.

In some embodiments, the glue can be a glue that in a ground state with certain fluidity such as molten state or liquid state at a high temperature and solidified at room temperature. The glue can have a high thermal conductivity, for example, the thermal conductivity of the glue can be greater than or equal to 2 W/(m·K) or 3 W/(m·K), so that on the one hand, the adhesive effect can be achieved, and on the other hand, the heat dissipation for the chip can be achieved with the thermal conductive layer.

Illustratively, the glue of this embodiment can be an elastic glue, where a thickness of the glue when there is no external force is a first thickness. The thickness of the thermal conductive layer 300 is a second thickness. The second thickness is greater than the first thickness, so that the thermal conductive layer 300 can fully contact with the chip 100 and the heat-dissipating metal sheet 200, and the thermal expansion of the chip 100 can be ensured.

Illustratively, when there is no external force, the thickness of the elastic glue is 0.05 mm, and the thickness of the thermal conductive layer 300 can be 0.06 mm, so that the thermal conductive layer is in full contact with the chip 100 and the heat-dissipating metal sheet 200, and air between the chip 100 and the heat-dissipating metal sheet 200 can be effectively excluded. At the same time, the elastic glue can bond the chip 100 and the heat-dissipating metal sheet 200 to ensure that the thermal relative position of the chip 100 and the heat-dissipating metal sheet 200 does not change.

Illustratively, the connection layer in this embodiment may be in a [symbol] -word shape or in a shape of a strip.

Illustratively, on the side of the heat-dissipating metal sheet 200 facing the chip 100, elastic glues in the [symbol] -word shape are disposed, a phase change material or a thermal conductive paste is spot coated to a blank area in the connection layer in the [symbol] -word shape, and then the side of the heat-dissipating metal sheet 200 provided with the glue is mounted on the chip 100.

Illustratively, on the side of the heat-dissipating metal sheet 200 facing the chip 100, strip-shaped elastic glues, such as strip-shaped glues disposed at intervals in one direction, are disposed, the phase change material or the thermal conductive paste are painted on blank areas in the strip-shaped glues arranged at intervals, and then the side of the heat-dissipating metal sheet 200 provided with the glues is mounted on the chip 100.

The elastic glue has certain elasticity, which can provide more space between the chip 100 and the heat-dissipating metal sheet 200 when the thermal conductive layer 200 expands, thus ensuring the stability of the chip module.

In this way, the connection layer is in a shape of [symbol] -word or in a shape of a strip, so that the phase change material or the thermal conductive paste can be located between different positions of the connection layer, so as to realize better heat dissipation for the thermal conductive layer 300, and at the same time, the relative position of the chip 100 and the heat-dissipating metal sheet 200 is fixed, which is convenient for installation and improves the operability in actual production.

Here, the heat-dissipating metal sheet 200 of this embodiment can be a copper sheet with a thickness of 0.1 mm˜1 mm, for example, the thickness of the copper sheet is 0.2 mm, 0.5 mm, etc., so that the heat-dissipating metal sheet 200 is neither too thin nor too thick, and the overall thickness of the packaged chip 100 is reduced while ensuring heat dissipation for the chip 100, thus saving costs.

In another embodiment, the connection layer of this embodiment may also be a welding layer including a solder, which welds the heat-dissipating metal sheet 200 and the chip 100 to prevent the relative positions of the heat-dissipating metal sheet 200 and the chip 100 from changing. Here, the chip 100 is not a bare chip, and there is an electroplating layer at the edge area of the chip. The heat-dissipating metal sheet 200 is welded with the electroplating layer. The welding layer welds the heat-dissipating metal sheet 200 and the chip 100 through the electroplating layer.

In this embodiment, the material and thickness of the welding layer are not specifically limited. For example, the material of the welding layer is tin, aluminum, iron, etc., as long as it can connect and fix the heat-dissipating metal sheet 200 and the chip 100, and ensure that the thermal conductive layer 300 can be fully contacted with the chip 100 and the heat-dissipating metal sheet 200, so that the relative position of the heat-dissipating metal sheet 200 and the chip 100 can be fixed, and the reliability of the chip module can be improved.

In another embodiment, as shown in FIG. 2, this embodiment may further include a heat sink 500. The heat sink 500 is installed on a plurality of the chip modules as stated above, and is fixedly connected with the heat-dissipating metal sheet 200 of each chip module, so as to realize the coplanar heat expansion of multiple chips.

Here, the heat sink 500 is a large-size heat sink, and a plurality of chips can use one or several (for example, two or three) heat sinks 500 for heat dissipation. In the case of using multiple heat sinks 500, the chip modules on the PCB 400 can be divided into regions, and a large-size heat sink is used in each region, for example, the regions are divided according to the size of the PCB 400 or the size of the heat sink 500, so that each heat sink 500 can be fully utilized and each chip 100 can be cooled.

In a practical application, there are hundreds of computing chips on the PCB, and each chip has a bare chip with a small heat source. In this embodiment, the phase change material layer or thermal conductive paste combined with the heat-dissipating metal plate 200 is used on the chip 100 to realize the thermal expansion of the bare chip, and at the same time, the integral heat sink 500 is used for heat dissipation, so as to realize the coplanar thermal conductive expansion and achieve an engineering effect that 1+1>2.

Illustratively, in this embodiment, a thermal conductive gel 600 is further included between the heat-dissipating metal sheet 200 and the heat sink 500.

Referring to FIG. 1 and FIG. 2, the thermal conductive layer 300 is disposed between the chip 100 and the heat-dissipating metal sheet 200, and the thermal conductive gel 600 is disposed between the heat-dissipating metal sheet 200 and the heat sink 500. The thermal conductive layer 300 is used for heat dissipation for the chip 100, and the thermal conductive gel 600 is not only used for heat dissipation for the heat-dissipating metal sheet 200, but also used for fixing the heat sink 500 on a plurality of heat-dissipating metal sheet 200, so as to realize a coplanar connection of multiple chips with the heat sink 500. Further, the structure of the thermal conductive layer 300, the heat-dissipating metal sheet 200, the thermal conductive gel 600 and the heat sink 500 can achieve better heat dissipation for the chip 100.

Here, the thermal conductive gel 600 has the function of filling large gaps and absorbing tolerance between multiple chips. Therefore, in this embodiment, the thermal conductive gel 600 is filled between the heat-dissipating metal sheet 200 and the heat sink 500, which eliminates the tolerances between the multiple chips while ensuring that the heat sink 500 is fixed on the heat-dissipating metal sheet 200, and fills the gaps between each heat-dissipating metal sheet 200 and the heat sink 500, thus realizing the coplanar connection of multiple chips with the heat sink 500.

Illustratively, a thickness of the thermal conductive gel 600 is greater than 0.2 mm, for example, the thickness of the thermal conductive gel 600 is 0.3 mm, 0.4 mm or 1 mm, so that the gap between each heat-dissipating metal sheet 200 and the heat sink 500 can be fully filled, the tolerance between multiple chips can be eliminated, and the coplanar connection of the multiple chips with the heat sink can be realized.

The combination of the thermal conductive layer 300 and the heat-dissipating metal sheet 200 in the present disclosure dissipates heat for the chip 100. The thermal conductive materials included in the thermal conductive layer 300 is: the phase change material or the thermal conductive paste, that is, the characteristics of good interfacial wettability, high thermal conductivity and thin coating of the phase change material or the thermal conductive paste is used to cooperate with the heat-dissipating metal sheet 200 on the top to achieve better thermal expansion. At the same time, a connection layer can be included between the chip 100 and the heat-dissipating metal sheets 200, which bonds and fixes the chip 100 and the heat-dissipating metal sheets 200, and the connection layer can adopt a glue, thus avoiding the problems of BSM coating and a chip welding of the chip, and having high practical operability. At the same time, the present disclosure also utilizes the gap filling function of the thermal conductive gel 600 on the top of the heat-dissipating metal sheet 200 to achieve multi-advantage combination, thus solving the technical problems of chip thermal expansion and multi-chip coplane, eliminating the tolerance among the multiple chips, and realizing the coplanar connection of multiple chips with the heat sink.

Based on the above embodiments, as shown in FIG. 2, the present disclosure also provides a circuit board, including a PCB 400 and a plurality of chip modules provided in the above embodiments, where one side of each of the chip modules away from the heat-dissipating metal 200 is fixed on the PCB 400.

Illustratively, as shown in FIG. 1 and FIG. 2, the circuit board further includes a heat sink 500; and the heat sink 500 is connected with the heat-dissipating metal sheet 200.

In the above embodiment, the heat sink 500 is assembled with the PCB 400, achieving the optimal structural combination of the chip 100, the thermal conductive layer 300, the heat-dissipating metal sheet 200, the thermal conductive gel 600 and the heat sink 500 for the whole PCB board, realizing the thermal expansion of multiple chips, eliminating the tolerance among the multiple chips through the thermal conductive gel 600, solving the technical problem of multi-chip coplane, and realizing the coplanar connection between the multiple chips and the heat sink.

The embodiment of the present disclosure also provides an electronic device including a circuit board provided by any of the aforementioned technical schemes.

The electronic device can be various computers, for example, the computer can be a server or a terminal device including the circuit board.

Illustratively, the circuit board can be used for a proof of work and/or a data processing in blockchain technology.

Illustratively, the electronic device may further include a heat-dissipating module, which may include an air-cooled heat-dissipating module and/or a liquid-cooled heat-dissipating module.

The air-cooled heat-dissipating module may include a fan.

In other embodiments, the electronic device may further include a chassis, and the circuit board is installed in the chassis.

Other implementations of the present disclosure will easily occur to those skilled in the art after considering the specification and practicing the disclosure disclosed herein. This application is intended to cover any variation, usage or adaptive change of the present disclosure, which follows the general principles of the present disclosure and includes common knowledge or customary technical means in the technical field which are not disclosed in the present disclosure. The specification and examples are to be regarded as exemplary only, with the true scope and spirit of the present disclosure being indicated by the following claims.

It should be understood that the present disclosure is not limited to the precise structure described above and shown in the drawings, and various modifications and changes can be made without departing from its scope. The scope of the present disclosure is limited only by the appended claims.

What is claimed is:

1. A chip module, comprising:
a chip;
a heat-dissipating metal sheet;
a thermal conductive layer located between the chip and the heat-dissipating metal sheet,
wherein a thermal conductive material included in the thermal conductive layer is a phase change material or a thermal conductive paste.

2. The chip module according to claim 1, wherein the chip module further comprises:
a connection layer located in an edge area of the chip, which fixes the heat-dissipating metal sheet and the chip;
the thermal conductive layer is at least located in a middle area of the chip; and
wherein the edge area is located outside the middle area.

3. The chip module according to claim 2, wherein,
the connection layer is:
an adhesive layer including a glue, wherein the adhesive layer adheres the heat-dissipating metal sheet and the chip;
or,
a welding layer including a solder, wherein the welding layer welds the heat-dissipating metal sheet and the chip.

4. The chip module according to claim 3, wherein the connection layer is in a [symbol] -word or in a shape of strip.

5. The chip module according to claim 3, wherein the glue is an elastic glue, and a thickness of the glue when there is no external force is a first thickness; and a thickness of the thermal conductive layer is a second thickness; and
the second thickness is greater than the first thickness.

6. The chip module according to claim 3, wherein the connection layer is the adhesive layer including the glue, and the chip is a bare chip.

7. The chip module according to claim 3, wherein the edge area of the chip has an electroplating layer;
the heat-dissipating metal sheet is welded with the electroplating layer; and
the welding layer welds the heat-dissipating metal sheet and the chip through the electroplating layer.

8. A circuit board, comprising:
a printed circuit board (PCB);
a plurality of chip modules, wherein each of the chip modules comprises a chip; a heat-dissipating metal sheet; and a thermal conductive layer located between the chip and the heat-dissipating metal sheet, wherein a thermal conductive material included in the thermal conductive layer is a phase change material or a thermal conductive paste;
wherein, one side of each of the chip modules away from the heat-dissipating metal sheet is fixed on the PCB.

9. The circuit board according to claim 8, wherein the chip module further comprises:
a connection layer located in an edge area of the chip, which fixes the heat-dissipating metal sheet and the chip;
the thermal conductive layer is at least located in a middle area of the chip; and
wherein the edge area is located outside the middle area.

10. The circuit board according to claim 9, wherein,
the connection layer is:
an adhesive layer including a glue, wherein the adhesive layer adheres the heat-dissipating metal sheet and the chip;
or,
a welding layer including a solder, wherein the welding layer welds the heat-dissipating metal sheet and the chip.

11. The circuit board according to claim 10, wherein the connection layer is in a [symbol] -word or in a shape of strip.

12. The circuit board according to claim 10, wherein the glue is an elastic glue, and a thickness of the glue when there is no external force is a first thickness; and a thickness of the thermal conductive layer is a second thickness; and
the second thickness is greater than the first thickness.

13. The circuit board according to claim 10, wherein the connection layer is the adhesive layer including the glue, and the chip is a bare chip.

14. The circuit board according to claim 10, wherein the edge area of the chip has an electroplating layer;
the heat-dissipating metal sheet is welded with the electroplating layer; and
the welding layer welds the heat-dissipating metal sheet and the chip through the electroplating layer.

15. The circuit board according to claim 8, wherein the circuit board further comprises:
a heat sink connected with the heat-dissipating metal sheet.

16. An electronic device comprising a circuit board:
the circuit board comprises a printed circuit board (PCB) and a plurality of chip modules;
wherein each of the chip modules comprises a chip; a heat-dissipating metal sheet; and a thermal conductive layer located between the chip and the heat-dissipating metal sheet, wherein a thermal conductive material included in the thermal conductive layer is a phase change material or a thermal conductive paste;
wherein, one side of each of the chip modules away from the heat-dissipating metal sheet is fixed on the PCB.

17. The electronic device according to claim 16, wherein the chip module further comprises:
a connection layer located in an edge area of the chip, which fixes the heat-dissipating metal sheet and the chip;
the thermal conductive layer is at least located in a middle area of the chip; and
wherein the edge area is located outside the middle area.

18. The electronic device according to claim 17, wherein,
the connection layer is:
an adhesive layer including a glue, wherein the adhesive layer adheres the heat-dissipating metal sheet and the chip;
or,
a welding layer including a solder, wherein the welding layer welds the heat-dissipating metal sheet and the chip.

19. The electronic device according to claim 18, wherein the connection layer is in a [symbol] -word or in a shape of strip.

20. The electronic device according to claim 18, wherein the glue is an elastic glue, and a thickness of the glue when there is no external force is a first thickness; and a thickness of the thermal conductive layer is a second thickness; and
the second thickness is greater than the first thickness.
